(19) United States
(12) Patent Application Publication
(10) Pub. No.: US 2011/0197955 A1
(43) Pub. Date: Aug. 18, 2011

(54) SOLAR MODULE HAVING AN ENCAPSULANT MOUNTING ADHESIVE

(75) Inventors: Dennis Booth, Grass Lake, MI (US); Timothy O'Neil, Clark Lake, MI (US); Sharon Loomis, Jackson, MI (US); Beverly Zimmerman, Spring Lake, MI (US); Paul Ruede, Brooklyn, MI (US); Paul Snowwhite, Dexter, MI (US); James Wood, Jackson, MI (US)

(73) Assignee: ADCO Products, Inc., Michigan Center, MI (US)

(21) Appl. No.: 13/061,266

(22) PCT Filed: Sep. 30, 2009
(86) PCT No.: PCT/US09/59034

§ 371 Date: Feb. 28, 2011

Related U.S. Application Data
(62) Division of application No. 61/101,304, filed on Sep. 30, 2008.

(51) Int. Cl. H01L 31/048; H01L 31/0203

(52) U.S. Cl. 136/251; 438/64; 257/E31.117

(57) ABSTRACT

A solar module includes a photovoltaic device that is partially encapsulated on a front side by a laminate layer. A front substrate is located over the laminate layer. The photovoltaic device is also at least partially encapsulated on a back side by a pressure sensitive adhesive layer. The adhesive layer acts as an encapsulant to protect the photovoltaic device as well as acts as an adhesive for attachment to a substrate.

### CROSS-REFERENCE TO RELATED APPLICATIONS

This application claims the benefit of U.S. Provisional Application No. 61/101,304 filed on Sep. 30, 2008. The disclosure of the above application is incorporated herein by reference.

### FIELD

The present invention relates to a solar module having an encapsulant mounting adhesive, and more particularly to a solar module having an encapsulant mounting adhesive on a back side of a photovoltaic device that encapsulates and seals the photovoltaic device and allows the solar module to be adhered directly to a substrate, such as a roof.

### BACKGROUND

Photovoltaic solar panels or modules generally include a photovoltaic device that is laminated and/or sandwiched between a plurality of layers. The majority of photovoltaic devices are rigid wafer-based crystalline silicon cells or thin film modules having cadmium telluride (Cd—Te), amorphous silicon, or copper-indium-diselenide (CuInSe₂) deposited on a substrate. The thin film solar modules may be either rigid or flexible. Flexible thin film cells and modules are created by depositing the photoactive layer and any other necessary substance on a flexible substrate. Photovoltaic devices are connected electrically to one another and to other solar panels or modules to form an integrated system.

Often the photovoltaic devices are encapsulated and laminated by ethylene-vinyl-acetate (EVA) films or other protective laminates, such as silicone polymers (e.g., polydimethylsiloxanes), thermoplastic polyurethanes (TPU), ionomeric polymers (e.g., PV5300 series by DuPont, Surlyn®), polyvinylbutyral (PVB), EPDM, and thermoplastic polyolefins (TPO). For example, one method of manufacturing solar modules includes laminating two sheets of glass together thereby encapsulating the photovoltaic device between the glass sheets. This affords protection for the photovoltaic components while allowing light to pass through the semi-conducting components that generate the electrical current. These two sheets of glass are “married” together to increase strength to meet certain mechanical and electrical requirements such as those outlined in IEC 61646 and UL1703. The lamination uses a film of crosslinkable ethylene vinyl acetate (EVA) or other laminate to heat laminate the two glass sheets together. This process requires that the glass sheets and the laminate be heated to about 155 degrees Celsius or higher under high vacuum (on the order of 0.15 Torr). This leads to a cycle time of about 20 minutes per part. However, this laminate must be further reinforced with a secondary sealant and moisture barrier around the outside edge due to the poor Moisture Vapor Transmission (MVT) characteristics of most laminates, including EVA.

A modification of this method uses a single layer of glass over the front or top of the solar module and depends upon other materials to provide additional strength and protection to the back of the module. These backing layers act as barriers to chemical attack or environmental degradation. Examples of these backing layers include fluorinated ethylene-propylene copolymer (FEP), poly(ethylene-co-tetrafluoroethylene) (ETFE), polyvinylidene fluoride (PVDF), polyvinyl fluoride (PVF), poly(tetrafluoroethylene) (PTFE) and combinations of these with other polymeric materials. Again, these backing layers must be laminated.

Still another method of manufacturing solar modules involves the lamination of several films together to create a flexible module. The photovoltaic layers are deposited onto a metallic support. This composite is then cut into individual cells, the cells are attached to the necessary conductors, and the cells are then laminated/encapsulated with a variety of protective layers. These layers of protective encapsulants provide mechanical and chemical protection from subsequent operations and the environment and may be chosen from the materials listed above.

All of these manufacturing methods mentioned above primarily use EVA as the adhesive to laminate the layers together. The EVA must resist ultraviolet light (UV), moisture, and must not contain any acidic constituents as these will attack the materials used to make the photovoltaic device, thereby reducing conductivity or causing an open circuit and reducing the life of the solar module.

The assembly of typical solar modules using EVA to laminate the various layers involves additional time and money during the lamination process. Accordingly, there is a need in the art for a backing substrate that meets the requirements for weatherability and moisture vapor transmission, is compatible with photovoltaic devices, has low conductivity, and adequate strength, while also providing good adhesion to a variety of possible substrates, and that is also quicker to assemble than current EVA lamination processes. In addition, there is a need in the art for making an encapsulated, sealed photovoltaic panel that is completed within the lamination step, saving time, weight and materials over the current processes.

### SUMMARY

The present invention provides a solar module. The solar module includes a photovoltaic device that is partially encapsulated on a front side by laminate layer. The laminate layer may include EVA. A front substrate is located over the laminate layer. The photovoltaic device is also at least partially encapsulated on a back side by a encapsulant mounting adhesive layer. The adhesive layer acts as an encapsulant and sealant to protect the photovoltaic device as well as acts as an adhesive. The adhesive layer is operable to be directly adhered to a substrate, such as a roof.

In one aspect of the present invention, the adhesive layer is comprised of a composition that exhibits adequate moisture and vapor transmission (MVT) characteristics, thermal stability, low conductivity, and low corrosivity to the other materials used to construct conventional photovoltaic devices, resistance to environmental exposure including direct sunlight, water, and chemical attack, as well as sufficient adhesive and mechanical properties to withstand hail, wind, foot traffic, or other potentially damaging events. The adhesive layer exhibits a balance of properties in which a high adhesive strength is contrasted with a cohesive strength that, while also is high, is not quite as high as the adhesive strength, such that when the solar module is stressed, the bond to the substrate and/or laminate is maintained, and the adhesive layer elongates slightly instead of breaking.

In another aspect of the present invention, the adhesive layer is comprised of various substances selected from polymers of acrylic, isobutylene, butadiene, acrylonitrile, epoxy, cyanoacrylate, EVA, polyester, polyethylene, polypropylene, urethane, silane modified urethane, silane terminated urethane, bitumens, natural rubber, block copolymer rubber, phenolic or hydrocarbon resins, and/or vinyl chloride.

In yet another aspect of the present invention, the adhesive layer is thermoplastic or thermoset and cures prior to or after removal from a laminating machine.

Further areas of applicability will become apparent from the description provided herein. It should be understood that the description and specific examples are intended for purposes of illustration only and are not intended to limit the scope of the present disclosure.

### DRAWINGS

FIG. 1 is a cross-sectional view of a portion of an embodiment of a solar module according to the principles of the present invention;

FIG. 2 is a cross-sectional view of the solar module shown in FIG. 1 attached to an exemplary substrate;

FIG. 3 is a cross-sectional view of a portion of another embodiment of a solar module according to the principles of the present invention;

FIG. 4 is a cross-sectional view of a portion of another embodiment of a solar module according to the principles of the present invention; and

FIG. 5 is a cross-sectional view of a portion of another embodiment of a solar module according to the present invention.

### DETAILED DESCRIPTION

The following description is merely exemplary in nature and is not intended to limit the present disclosure, application, or uses.

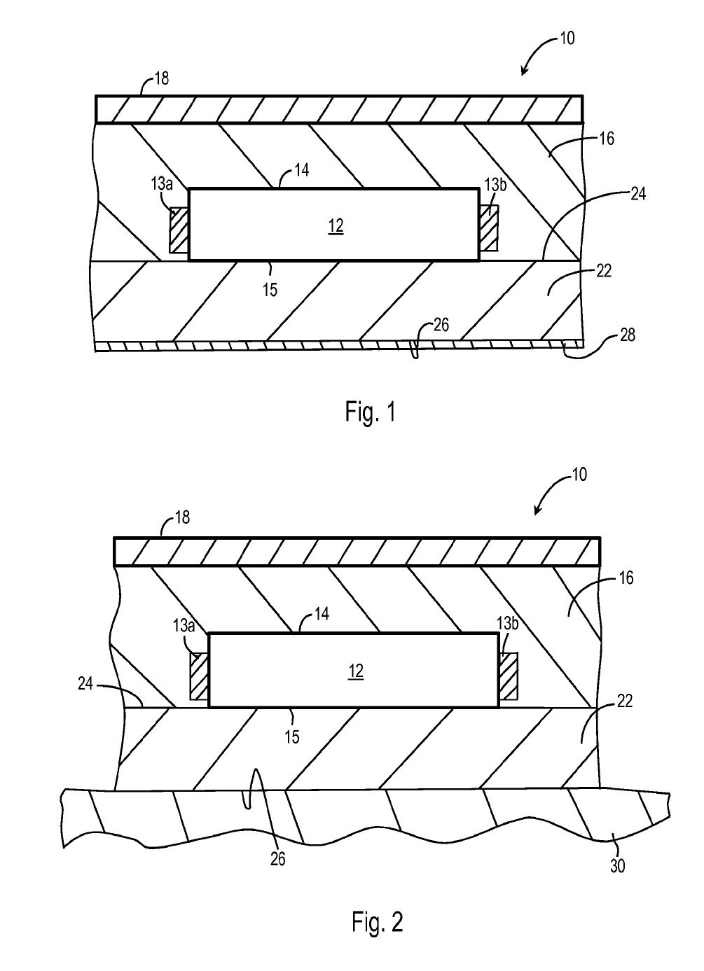

With reference to FIG. 1 a solar module according to the principles of the present invention is generally indicated by reference number 10. The solar module 10 includes at least one photovoltaic device 12. In a preferred embodiment, a plurality of photovoltaic devices 12 are located within the solar module 10 connected in series or in parallel or a combination thereof to achieve a desired output voltage. It should be appreciated that any number of photovoltaic devices 12 may be employed without departing from the present invention. The photovoltaic device 12 is operable to absorb light and generate a current in response to the absorption of the light. The current produced by the photovoltaic device 12 is communicated via bus bars 13a, 13b or other conductive materials, wires, or layers, to wires or lead lines (not shown) that exit the solar module 10. The lead lines communicate with a junction box (not shown) in order to distribute the electrical current generated by the solar module 10 to a power circuit.

Accordingly, the photovoltaic device 12 may take various known forms without departing from the scope of the present invention. For example, the photovoltaic device 12 may be a thin film cell with various layers, such as, for example, cadmium telluride (Cd—Te) and cadmium sulfide (CdS), amorphous silicon, or copper-indium-diselenide (CuInSe₂). Alternatively, the photovoltaic device 12 may be a crystalline silicon wafer embedded in a laminating film or gallium arsenide deposited on germanium or another substrate. Other types of photovoltaic devices 12 that may be employed include organic semiconductor cells having conjugate polymers as well as dye-sensitized metal oxides including wet metal oxides and solid metal oxides. The photovoltaic device 12 may be either rigid or flexible.

The photovoltaic device 12 generally includes a front side 14, or light incident side that is intended to face the sunlight, and a back side 15. The back side 15 is located opposite the front side 14. The front side 14 is at least partially, and in a preferred embodiment completely, encapsulated by a laminate layer 16. The laminate layer 16 is preferably a cross-linkable ethyl vinyl acetate (EVA). However, it should be appreciated that other laminates or encapsulants may be employed without departing from the scope of the present invention. The laminate layer 16 is used to partially encapsulate the photovoltaic device 12 to protect the photovoltaic device 12 from contamination and from the environment.

A front substrate or layer 18 is located overtop the laminate layer 16. The front substrate 18 is preferably glass or a similar substance operable to allow wavelengths of sunlight to pass therethrough. Alternatively, the front substrate 18 may be a plastic film such as polyvinylflouride.

The photovoltaic device 12 is also at least partially encapsulated on the back side 15 by a pressure sensitive, encapsulant mounting adhesive layer 22. The adhesive layer 22 operates as an encapsulant, structural protective backing, sealant and as a mounting adhesive. The adhesive layer 22 includes a first side 24 and a second side 26 opposite the first side 24. The first side 24 is adhered to the laminate layer 16 and to the back side 15 of the photovoltaic device 12. The second side 26 is protected by a release liner 28. The release liner 28 covers the entire second side 26 of the adhesive layer 22 during transport and storage of the solar module 10.

Turning to FIG. 2, the release liner 28 is removed prior to installation of the solar module 10 on an exemplary substrate 30. The substrate 30 may take various forms, such as a rack, roof membrane, or roof deck, and be comprised of any number of materials including compositions, such as, for example, an ethylene propylene diene terpolymer (EPDM), a thermoplastic olefin (TPO), a polyvinyl chloride (PVC), a styrene-butadiene-styrene (SBS) modified bitumen, atactic polypropylene (APP) modified bitumen, galvanized steel, aluminum, stainless steel, and painted steel that includes polyvinylidene fluoride (PVDF), i.e. KYNAR™ coated steel. The adhesive layer 22 adheres the solar module 10 to the substrate 30.

The adhesive layer 22 exhibits adequate MVT characteristics, thermal stability, low conductivity, and low corrosivity to the other materials used to construct conventional photovoltaic devices 12, resistance to environmental exposure including direct sunlight, water, and chemical attack, as well as sufficient adhesive and mechanical properties to withstand hail, wind, foot traffic, or other potentially damaging events, including cutting and puncture. The adhesive layer 22 may be comprised of various substances, such as, for example, polymers of acrylic, isobutylene, butadiene, acrylonitrile, epoxy, cyanoacrylate, EVA, polyester, polyethylene, polypropylene, urethane, silane modified urethane, silane terminated urethane, bitumens, natural rubber, block copolymer rubber, phenolic or hydrocarbon resins, and/or vinyl chloride. The adhesive layer 22 may be thermoplastic or thermosetting and may cure prior to removal from the laminating machine or after removal, (i.e. cure in place) by various mechanisms. In one embodiment, the adhesive layer 22 is a co-extrusion.

In a preferred embodiment, the adhesive layer 22 is comprised of a composition disclosed in commonly assigned U.S. Patent Application No. 61/041,760, filed Apr. 4, 2008, hereby incorporated by reference as if fully disclosed herein. More specifically, the adhesive layer 22 is comprised of a pressure sensitive adhesive composition that includes an uncured or not fully cured rubbery polymer blend, at least one compatible tackifier, and a curing agent blend. In one embodiment, the adhesive composition of the present invention includes: a) from about 10-60% of the rubbery polymer blend, b) from about 25-85% of the compatible tackifier, and c) from about 1-6% of the curing agent blend. The adhesive composition also preferably includes other components including plasticizers, water scavengers or desiccants, antioxidants, fillers and rheology modifiers, colorants and UV absorbers, and stabilizers.

The uncured or not fully cured rubbery polymer blend consists of two ethylene-propylene diene terpolymers (e.g., ethylene propylene norbornadiene terpolymer and ethylene propylene dicyclopentadiene terpolymer), ethylene propylene hexadiene terpolymer, chlorobutyl rubber, and two separate molecular weight polyisobutylenes. The uncured rubbery polymers impart strength and adhesion to the composition. Additionally, the chlorobutyl rubber acts as a cross-linking portion of the polymer blend during curing. Chemical derivatives and combinations of these uncured rubber polymers may also be used, for example, halogenated butyl rubber or a halogenated copolymer of p-methylstyrene and isobutylene, other polyolefins, and combinations thereof.

The tackifiers preferably consist of polybutene homopolymer and phenolic tackifier resin. The polybutene homopolymer also acts as an adhesion promoter. Chemical derivatives and combinations of these tackifiers may also be employed in the composition without departing from the scope of the present invention.

The curing agent blend preferably consists of one or more of a cure accelerator, a sulfur or peroxide activator, and a curing and vulcanizing agent. Exemplary cure accelerators include tetramethylthiuram disulfide and benzothiazyl disulfide. An exemplary sulfur activator includes zinc oxide. An exemplary curing and vulcanizing agent includes sulfur. Chemical derivatives and combinations of these cure accelerators, sulfur activators, and curing and vulcanizing agents may also be employed in the composition without departing from the scope of the present invention.

A suitable plasticizer for use in the present composition includes, but is not limited to, paraffinic process oil. Chemical derivatives and combinations of plasticizers may also be employed in the composition without departing from the scope of the present invention.

Suitable fillers and rheology modifiers for use in the present composition include, but are not limited to, one or more of calcium carbonate, talc, and fumed silica. Chemical derivatives and combinations of these fillers and rheology modifiers may also be employed in the composition without departing from the scope of the present invention.

A suitable water scavenger for use in the present composition includes, but is not limited to, calcium oxide. Chemical derivatives and combinations of calcium oxide may also be employed in the composition without departing from the scope of the present invention. Suitable desiccants for use in the present composition include, but are not limited to, molecular sieves, calcium sulfate, calcium chloride, and silica gel.

A suitable antioxidant for use in the present composition includes, but is not limited to, tetrakismethylene (3,5-di-t-butyl-4-hydroxyhydrocinnamate) methane. Chemical derivatives and combinations of compatible antioxidants may also be employed in the composition without departing from the scope of the present invention.

A suitable colorant and ultra-violet radiation absorber for use in the present composition includes, but is not limited to, carbon black. Chemical derivatives and combinations of compatible colorants and UV absorbers may also be employed in the composition without departing from the scope of the present invention.

A suitable stabilizer for use in the present composition includes, but is not limited to, tetrachloro-p-benzoquinone. Chemical derivatives and combinations of compatible stabilizers may also be employed in the composition without departing from the scope of the present invention.

In order that the invention may be more readily understood, reference is made to the following example which is intended to illustrate the invention, but not limit the scope thereof:

| | | | Preferred | |
|---|---|---|---|---|
| | | | Composition | Exemplary |
| | | | Range | Composition |
| | Chemical Type | Function | Weight % | Weight % |
| 1 | Paraffinic Process Oil | Plasticizer | 1-5 | 1.51% |
| 2 | Calcium Carbonate | Filler, rheology adjustment | 1-5 | 2.50% |
| 3 | Calcium Oxide | Water scavenger | 2-8 | 4.95% |
| 4 | Tetrakismethylene (3,5-di-t-butyl-4-hydroxy- | Antioxidant | 0.1-0.5 | 0.30% |
| | hydrocinnamate) methane | | | |
| 5 | Polybutene Homopolymer | Tackifier, adhesion promoter | 20-60 | 40.66% |
| 6 | Talc | Filler, rheology modifier | 0-5 | 2.47% |
| 7 | Phenolic Tackifier Resin | Tackifier | 5-25 | 10.11% |
| 8 | Polyisobutylene | Polymer, imparts strength and | 0-10 | 4.35% |
| | | adhesion | | |
| 9 | Fumed Silica | Rheology modifier | 0-3 | 0.50% |
| 10 | Carbon Black | Colorant, UV absorber | 2-5 | 2.47% |
| 11 | Ethylene Propylene Diene Terpolymer | Polymer, imparts strength and | 1-5 | 2.18% |
| | | adhesion | | |
| 12 | Ethylene Propylene Diene Terpolymer | Polymer, imparts strength and | 2-10 | 8.67% |
| | | adhesion | | |
| 13 | Polyisobutylene | Polymer, imparts strength and | 2-10 | 4.95% |
| | | adhesion | | |
| 14 | Curing Agent Blend (Consisting of the following) | | 1.5-5 | 2.35% |
| | Tetramethylthiuram disulfide | Cure accelerator | 0-5 | 0.18% |
| | Benzothiazyl disulfide | Cure accelerator | 0-5 | 0.20% |
| | Zinc oxide | Sulfur activator | 0-5 | 1.27% |
| | Sulfur | Curing/vulcanizing agent | 0-5 | 0.34% |
| | Paraffinic Process Oil | Plasticizer in Curing Agent Blend | 0-5 | 0.36% |
| 15 | Tetrachloro-p-benzoquinone | Stabilizer | 0.1-0.5 | 0.15% |
| 16 | Chlorobutyl Rubber | Polymer, imparts strength and | 5-25 | 11.88% |
| | | adhesion, cross-linking portion of | | |
| | | polymer | | |
| | | | | 100.00% |

Exemplary Components by Trade Name:
1. Procoil 8240/Sunpar 2280
2. Armco 70
3. Mississippi Lime
4. BNX/Irganox 1010
5. H-300 Poly
6. Mistron
7. 29095 Durez
8. SDG-8650
9. HiSil 233
10. Corax N-650
11. Trilene 65 or 67
12. Nordel IP-4520
13. Efrolen P-85
14. BL/GRN Cure Blend
15. Vulklor
16. Exxpro 3433 or Lanxess 2030

The adhesive composition of the adhesive layer 22 exhibits a peel strength of at least 715 grams/cm at room temperature, at least 300 grams/cm at 70 degrees Celsius, and supports a static load of at least 300 grams at 70 degrees Celsius, preferably for a minimum of 96 hours. As noted above, the composition is initially uncured having a tensile strength from about 5 psi to about 40 psi. Full curing of the composition occurs after placement on the substrate 30. Full curing is achieved when further exposure to elevated temperatures do not change the adhesivity, strength, or static load resistance of the composition. The fully cured composition has a tensile strength of about 50 psi to about 100 psi. Exemplary test results performed under UL 746C ratings of 90° C. and 105° C. using Option No. 1 times and temperatures is summarized below:

| | Average |
|---|---|
| Test Conditions: | Strength: |
| 175 hrs @ 156° C. | 33.8 psi |
| 300 hrs @ 156° C. | 42.3 psi |
| 600 hrs @ 156° C. | 57.6 psi |
| 175 hrs @ 176° C. | 36.2 psi |
| 300 hrs @ 176° C. | 40.5 psi |
| 600 hrs @ 176° C. | 64.5 psi |

The adhesive layer 22 remained tacky and pliable after the elevated temperature ageing.

In addition, the adhesive layer 22 exhibits low conductivity, as shown by the exemplary test results tested under ASTM-257 and summarized below:

| | |
|---|---|
| Rv | Rs |

| | | | |
|---|---|---|---|
| Average | 5.18E+15 ρ | Average | 3.04E+14σ |
| Value | | | |
| Standard | 2.2E+15ρ | Standard | 6.18E+13σ |
| Deviation | | Deviation | |

In the above table, Rᵥ refers to volume resistivity and Rₛ refers to surface resistivity. Finally, the adhesive composition exhibits an equilibrated MVTR of at most, 0.4 g/m²/day, typically less than 0.2 g/m²/day for 60-80 mil thicknesses at 38° C.

The compositions described above are blends of polymers that contribute to the proper balance of properties through its cure potential. Polyisobutylene rubber has no cure potential and thus acts as a polymer diluent. Ethylene propylene terpolymers have unsaturation levels as high as 10%.

In addition, the composition of the adhesive layer 22 may include a reinforcing scrim or material in order to enhance the cut and puncture resistance of the completed solar module 10. The reinforcing material is mixed within the adhesive composition within the adhesive layer 22 or laid between co-extruded layers of the adhesive composition within the adhesive layer 22. The reinforcing material may be fibrous or a continuous or nearly continuous film, sheet, mat or roving. The reinforcing material may also be woven, spunbonded, needle punched, chopped or a continuous filament. The reinforcing material may be comprised of glass, polyester, aramid, nylon, polyolefin or other material resistant to mechanical forces, in fibrous or sheet form. In a preferred embodiment, the reinforcing material is glass and in a more-preferred embodiment the reinforcing material is in a continuous filament mat or tissue form.

The entire solar module 10 is assembled within a laminating step where all the layers of the solar module 10 including the photovoltaic devices 12, the laminate layer 16, the front substrate 18, the adhesive layer 22, and the release liner 26 are stacked during a lay-up step. Next, these stacked layers are vacuum sealed in a lamination machine. The vacuum seal is used to remove potential air bubbles from the laminate layer 16. The vacuum is preferably held for 5 to 7 minutes at 138 degrees Celsius. However, other times and temperatures may be employed without departing from the scope of the present invention. Finally, the layers are pressed or pressurized. The press is preferably held for approximately 15 minutes at 138 degrees Celsius. Again, it should be appreciated that the timing and temperature may vary without departing from the scope of the present invention. The completed solar module 10 is then removed from the laminating machine and the release liner 28 applied to the exposed surface of the adhesive layer 22. By stacking the adhesive layer 22 with the laminate layer 16, a lamination step required in previous solar module construction is eliminated.

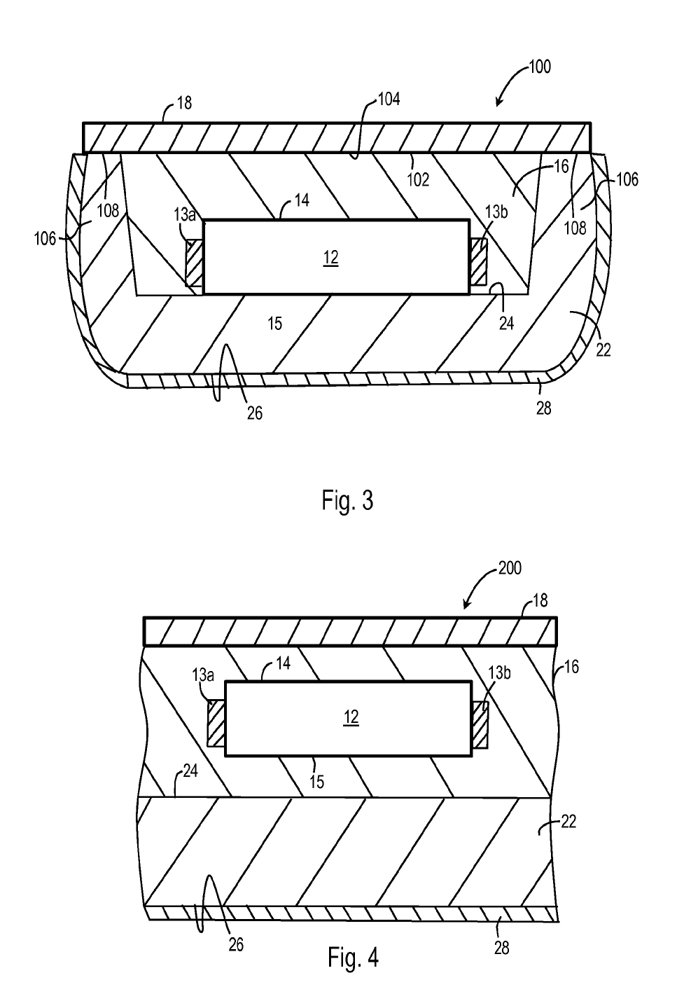

Turning to FIG. 3, an alternate embodiment of a solar module is generally indicated by reference number 100. The solar module 100 is similar to the solar module 10 shown in FIGS. 1 and 2 and accordingly like components are indicated by like reference numbers. However, in the solar module 100, the adhesive layer 22 additionally acts as an edge sealant that completely encapsulates the laminate layer 16. In the example shown, the laminate layer 16 is adhered to a first portion 102 of a back side 104 of the front layer 18. The adhesive layer 22 includes end portions 106 that curve up and encapsulate the laminate layer 16. The end portions 106 of the adhesive layer 22 are adhered to a second portion 108 of the back side 104 of the front layer 22. The second portion 108 is peripherally located around the first portion 106 such that the laminate layer 16 is completely encapsulated by cooperation of the front layer 18 and the adhesive layer 22. Since the adhesive layer 22 has suitable MVTR characteristics, the need for any edge sealants is eliminated. Alternatively, the adhesive layer 22 may extend around the sides of the front layer 18 and adhere to the sides of the front layer 18 and/or to a portion of the top surface of the front layer 18.

Turning to FIG. 4, an alternate embodiment of a solar module according to the principles of the present invention is generally indicated by reference number 200. The solar module 200 is similar to the solar module 10 shown in FIGS. 1 and 2 and therefore like components are indicated by like reference numbers. However, in the solar module 200, the photovoltaic device 12 is entirely encapsulated by the laminating layer 16. Accordingly, the adhesive layer 22 does not adhere to the back side 15 of the photovoltaic device 12 and instead adheres completely to the laminate layer 16.

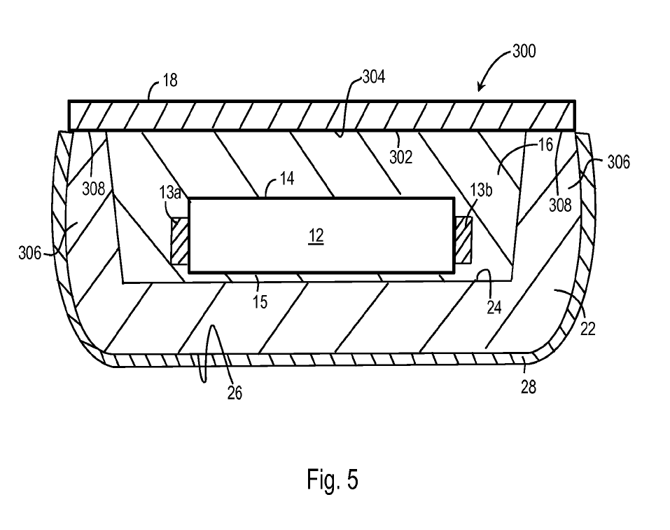

With reference to FIG. 5, another embodiment of a solar module is indicated by reference number 300. The solar module 300 is similar to the solar module 200 shown in FIG. 4 and accordingly like components are indicated by like reference numbers. However, in the solar module 300, the adhesive layer 22 additionally acts as an edge sealant that completely encapsulates the laminate layer 16. In the example shown, the laminate layer 16 is adhered to a first portion 302 of a back side 304 of the front layer 18. The adhesive layer 22 includes end portions 306 that curve up and encapsulate the laminate layer 16. The end portions 306 of the adhesive layer 22 are adhered to a second portion 308 of the back side 304 of the front layer 22. The second portion 308 is peripherally located around the first portion 306 such that the laminate layer 16 is completely encapsulated by cooperation of the front layer 18 and the adhesive layer 22. Since the adhesive layer 22 has suitable MVTR characteristics, the need for any edge sealants is eliminated. Alternatively, the adhesive layer 22 may extend around the sides of the front layer 18 and adhere to the sides of the front layer 18 and/or to a portion of the top surface of the front layer 18.

The description of the invention is merely exemplary in nature and variations that do not depart from the gist of the invention are intended to be within the scope of the invention. Such variations are not to be regarded as a departure from the spirit and scope of the invention.

We claim the following:

1. A solar module comprising:
a photovoltaic device operable to generate an electrical current from light, the photovoltaic device having a front side for receiving light;
a laminate at least partially covering the front side of the photovoltaic device;
a front layer affixed to the laminate wherein the front layer is at least partially transparent; and
an adhesive having a first adhesive side and a second adhesive side opposed to the first adhesive side, wherein the first adhesive side is adhered to at least the laminate and to the front layer along a periphery of the front layer.

2. The solar module of claim 1 wherein the photovoltaic device includes a back side opposed to the front side, and wherein the laminate covers the back side of the photovoltaic device.

3. The solar module of claim 1 wherein the photovoltaic device includes a back side opposed to the front side, and wherein the first adhesive side of the adhesive is adhered to the back side of the photovoltaic device.

4. The solar module of claim 1 further comprising a release liner removably attached to the second adhesive side of the adhesive.

5. The solar module of claim 1 wherein the adhesive and the front layer completely surround the laminate layer and the photovoltaic device.

6. The solar module of claim 1 wherein the front layer includes a top surface and a bottom surface opposed to the top surface, wherein the laminate is in contact with the front layer on a first portion the bottom surface and the adhesive is adhered to the front layer on a second portion of the bottom surface, and wherein the second portion is disposed along a periphery of the first portion.

7. The solar module of claim 1 wherein the adhesive includes a reinforcing material operable to affect the cut and puncture resistance of the adhesive.

8. The solar module of claim 7 wherein the reinforcing material is dispersed within the adhesive.

9. The solar module of claim 7 wherein the reinforcing material is comprised of at least one layer disposed between the first adhesive side and the second adhesive side.

10. The solar module of claim 7 wherein the reinforcing material is selected from a group consisting of glass, polyester, aramid, nylon, and polyolefin.

11. The solar module of claim 1 wherein the adhesive has a moisture vapor transmission rate of less than about 0.5 g/m²/day at 38° C. at a thickness of 60-80 mils.

12. The solar module of claim 1 wherein the adhesive has a moisture vapor transmission rate of less than about 0.3 g/m²/day at 38° C. at a thickness of 60-80 mils.

13. The solar module of claim 1 wherein the adhesive has a moisture vapor transmission rate of less than about 0.2 g/m²/day at 38° C. at a thickness of 60-80 mils.

14. The solar module of claim 1 wherein the adhesive has a tensile strength from about 5 pounds per square inch (psi) to about 20 psi when uncured and has a tensile strength over 20 psi when cured.

15. The solar module of claim 1 wherein the adhesive has a volume resistivity of approximately 5E-15ρ and a surface resistivity of approximately 3E+14σ.

16. The solar module of claim 1 wherein the laminate is selected from the group consisting of ethylene vinyl acetate, polydimethylsiloxanes, thermoplastic polyurethanes (TPU), ionomeric polymers, polyvinylbutyral (PVB), EPDM, and thermoplastic polyolefins (TPO).

17. The solar module of claim 1 wherein the adhesive comprises:
a rubbery polymer blend including ethylene propylene norbornadiene terpolymer, ethylene propylene dicyclopentadiene terpolymer, ethylene propylene hexadiene terpolymer, halobutyl rubber, polyisobutylene, polybutene, or other polyolefins, or combinations thereof;
at least one of a tackifier or a curing agent blend, wherein the tackifier includes a phenolic tackifier resin, and wherein the curing agent blend includes a cure accelerator, a sulfur or peroxide activator, and a curing vulcanizing agent; and
a desiccant or water scavenger present in an amount from about 2% to about 8% by weight.

18. The solar module of claim 17 wherein the water scavenger is calcium oxide.

19. The solar module of claim 1 wherein the adhesive is comprised of polymers of acrylic, isobutylene, butadiene, acrylonitrile, epoxy, cyanoacrylate, EVA, polyester, polyethylene, polypropylene, urethane, silane modified urethane, silane terminated urethane, bitumens, natural rubber, block copolymer rubber, phenolic or hydrocarbon resins, or vinyl chloride, or combinations thereof.

20. The solar module of claim 1 wherein the adhesive is thermoplastic.

21. The solar module of claim 1 wherein the adhesive is thermosetting.

22. The solar module of claim 1 wherein the adhesive cures prior to removal from a laminating machine.

23. The solar module of claim 1 wherein the adhesive cures after removal from a laminating machine.

24. The solar module of claim 1 wherein the photovoltaic device is a flexible photovoltaic device.

25. A solar module comprising:
a photovoltaic device operable to generate an electrical current from light, the photovoltaic device having a front side for receiving the light;
a laminate at least partially covering the front side of the photovoltaic device;
a front layer affixed to the laminate wherein the front layer is at least partially transparent; and
an adhesive layer having a first adhesive side and a second adhesive side opposed to the first adhesive side, wherein the first adhesive side is adhered to at least the laminate, and wherein the adhesive layer comprises:
a rubbery polymer blend including ethylene propylene norbornadiene terpolymer, ethylene propylene dicyclopentadiene terpolymer, ethylene propylene hexadiene terpolymer, halobutyl rubber, polyisobutylene or polybutene or other polyolefins or combinations thereof;
at least one of a tackifier or a curing agent blend, wherein the tackifier includes a phenolic tackifier resin, and wherein the curing agent blend includes a cure accelerator, a sulfur or peroxide activator, and a curing vulcanizing agent; and
a desiccant or water scavenger present in an amount from about 2% to about 8% by weight.

26. The solar module of claim 25 wherein the photovoltaic device includes a back side opposed to the front side, and wherein the laminate covers the back side of the photovoltaic device.

27. The solar module of claim 25 wherein the photovoltaic device includes a back side opposed to the front side, and wherein the first adhesive side of the adhesive layer is adhered to the back side of the photovoltaic device.

28. The solar module of claim 25 further comprising a release liner removably attached to the second adhesive side of the adhesive layer.

29. The solar module of claim 25 wherein the adhesive layer includes a reinforcing material operable to affect the cut and puncture resistance of the adhesive layer.

30. The solar module of claim 29 wherein the reinforcing material is dispersed within the adhesive layer.

31. The solar module of claim 29 wherein the reinforcing material is comprised of at least one layer disposed between the first adhesive side and the second adhesive side.

32. The solar module of claim 29 wherein the reinforcing material is selected from a group consisting of glass, polyester, aramid, nylon, and polyolefin.

33. The solar module of claim 25 wherein the adhesive layer has a moisture vapor transmission rate of less than about 0.5 g/m²/day at 38° C. at a thickness of 60-80 mils.

34. The solar module of claim 25 wherein the adhesive layer has a moisture vapor transmission rate of less than about 0.3 g/m²/day at 38° C. at a thickness of 60-80 mils.

35. The solar module of claim 25 wherein the adhesive layer has a moisture vapor transmission rate of less than about 0.2 g/m²/day at 38° C. at a thickness of 60-80 mils.

36. The solar module of claim 25 wherein the adhesive layer has a tensile strength from about 5 pounds per square inch (psi) to about 40 psi when uncured and has a tensile strength from about 50 psi to about 100 psi when cured.

37. The solar module of claim 25 wherein the adhesive layer has a volume resistivity of approximately 5E-15ρ and a surface resistivity of approximately 3E-14σ.

38. The solar module of claim 25 wherein the laminate layer is comprised of ethylene vinyl acetate, polydimethylsiloxanes, thermoplastic polyurethanes (TPU), ionomeric polymers, polyvinylbutyral (PVB), EPDM, or thermoplastic polyolefins (TPO).

39. The solar module of claim 25 wherein the water scavenger is calcium oxide.

40. The solar module of claim 25 wherein the adhesive layer and the front layer completely surround the laminate layer and the photovoltaic device.

41. A method for assembling a solar module, the method comprising:
stacking a front layer, a laminate layer, at least one photovoltaic device, an adhesive layer, and a release liner to form a stack in a laminating machine;
applying a vacuum to the stack to remove air from the stack;
applying pressure to the stack at an elevated temperature to form the solar module; and
removing the solar module from the laminating machine.

42. The method of claim 41 whereby an encapsulated, sealed photovoltaic panel is completed within the lamination step.
